(19) United States
(12) Patent Application Publication
(10) Pub. No.: US 2026/0282898 A1
(43) Pub. Date: Sep. 17, 2026

(54) PACKAGE STRUCTURE AND MANUFACTURING METHOD THEREOF

(71) Applicant: Taiwan Semiconductor Manufacturing Company, Ltd., Hsinchu (TW)

(72) Inventors: Wensen Hung, Hsinchu County (TW); Kris Lipu Chuang, Hsinchu City (TW)

(73) Assignee: Taiwan Semiconductor Manufacturing Company, Ltd., Hsinchu (TW)

(21) Appl. No.: 19/082,148

(22) Filed: Mar. 17, 2025

(51) Int. Cl. H10W 40/22; H10W 40/25; H10W 42/00; H10W 95/00; H10W 90/00

(52) U.S. Cl. CPC H10W 40/22; H10W 40/25; H10W 42/121; H10W 95/00; H10W 90/00

(57) ABSTRACT

A device includes a semiconductor package including a first side and a second side opposite to each other, a substrate coupled to the second side of the semiconductor package, and a lid coupled to the substrate and the first side of the semiconductor package. The lid includes a first surface and a second surface opposite to each other, the second surface faces the semiconductor package, and the first surface is flatter than the second surface.

### BACKGROUND

In the packaging of integrated circuits, semiconductor dies may be stacked through bonding, and may be bonded to other package components such as interposers and package substrates. The resulting package structures are known as three-dimensional integrated circuits (3DICs). However, warpage and heat dissipation issues are challenges in the 3DICs. As a result, there is continuous effort in developing new mechanisms of forming package structures with better reliability and performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1E are schematic cross-sectional views of various stages of manufacturing a package structure, in accordance with some embodiments.

FIG. 1F is a schematic perspective view of a lid, in accordance with some embodiments.

FIG. 1G is a schematic cross-sectional view of a package assembly, in accordance with some embodiments.

FIG. 2A is a schematic cross-sectional view of a package structure, in accordance with some embodiments.

FIG. 2B is a schematic perspective view of a lid, in accordance with some embodiments.

FIG. 2C is a schematic cross-sectional view of a package assembly, in accordance with some embodiments.

FIGS. 3A-3C are schematic cross-sectional views of various stages of manufacturing a package structure, in accordance with some embodiments.

FIG. 3D is a schematic cross-sectional view of a package assembly, in accordance with some embodiments.

FIGS. 4A-4B are schematic cross-sectional views of various stages of manufacturing a package structure, in accordance with some embodiments.

FIG. 4C is a schematic cross-sectional view of a package assembly, in accordance with some embodiments.

FIG. 5A is a schematic cross-sectional view of a lid, in accordance with some embodiments.

FIG. 5B is a schematic perspective view of a lid, in accordance with some embodiments.

FIGS. 5C-5D are schematic cross-sectional views of various stages of manufacturing a package structure, in accordance with some embodiments.

FIG. 6A is a schematic cross-sectional view of a lid, in accordance with some embodiments.

FIG. 6B is a schematic perspective view of a lid, in accordance with some embodiments.

FIG. 6C is a schematic cross-sectional view of a package structure, in accordance with some embodiments.

FIG. 7A is a schematic perspective view of a lid, in accordance with some embodiments.

FIG. 7B is a schematic top view of a lid, in accordance with some embodiments.

FIG. 7C is a schematic cross-sectional view of a package assembly, in accordance with some embodiments.

FIG. 8A is a schematic perspective view of a lid, in accordance with some embodiments.

FIG. 8B is a schematic cross-sectional view of a package assembly, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

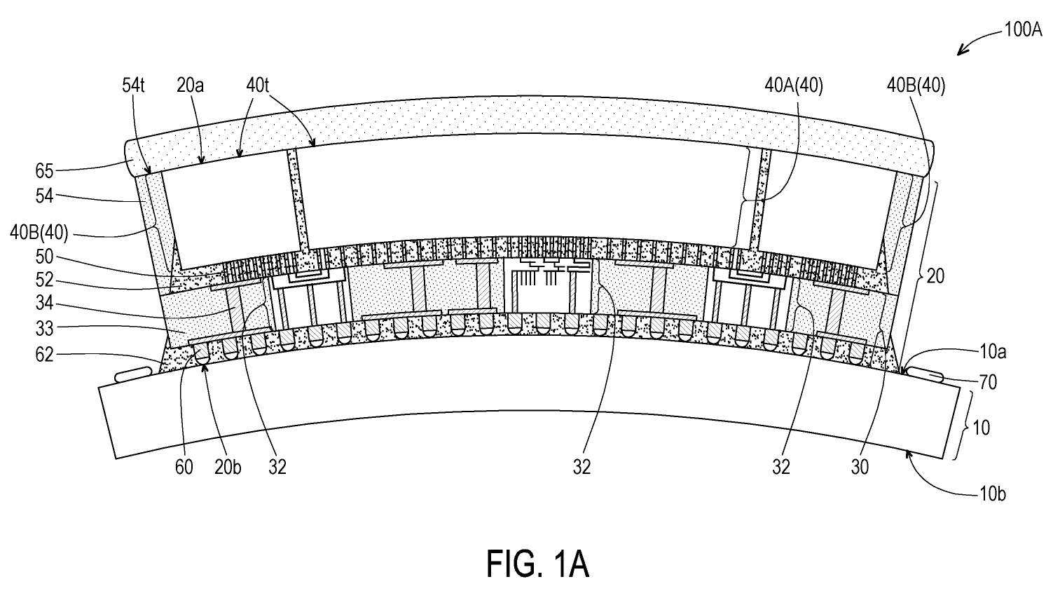

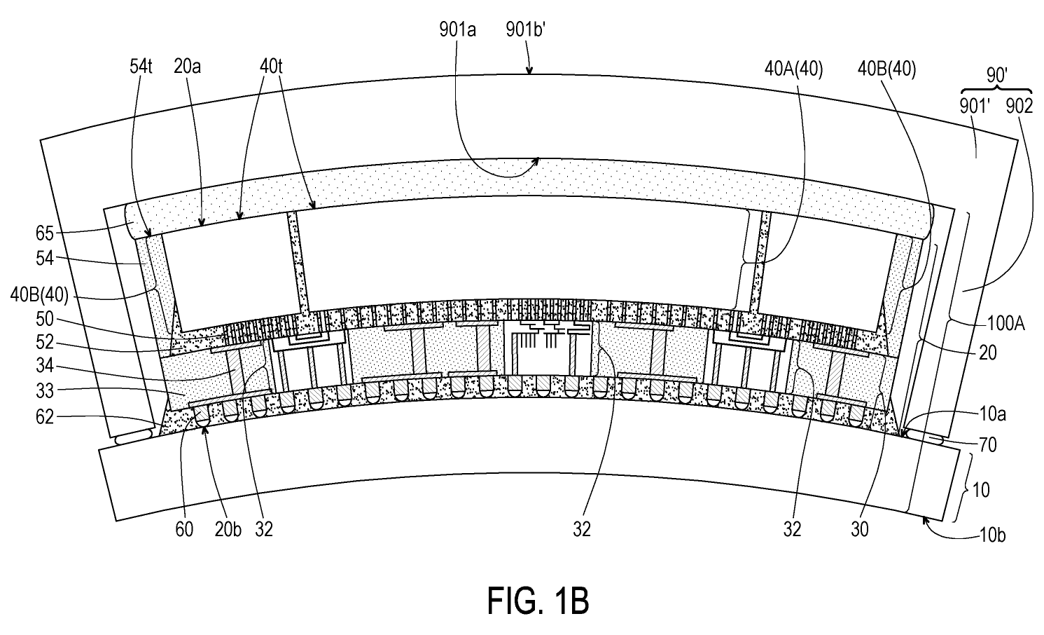

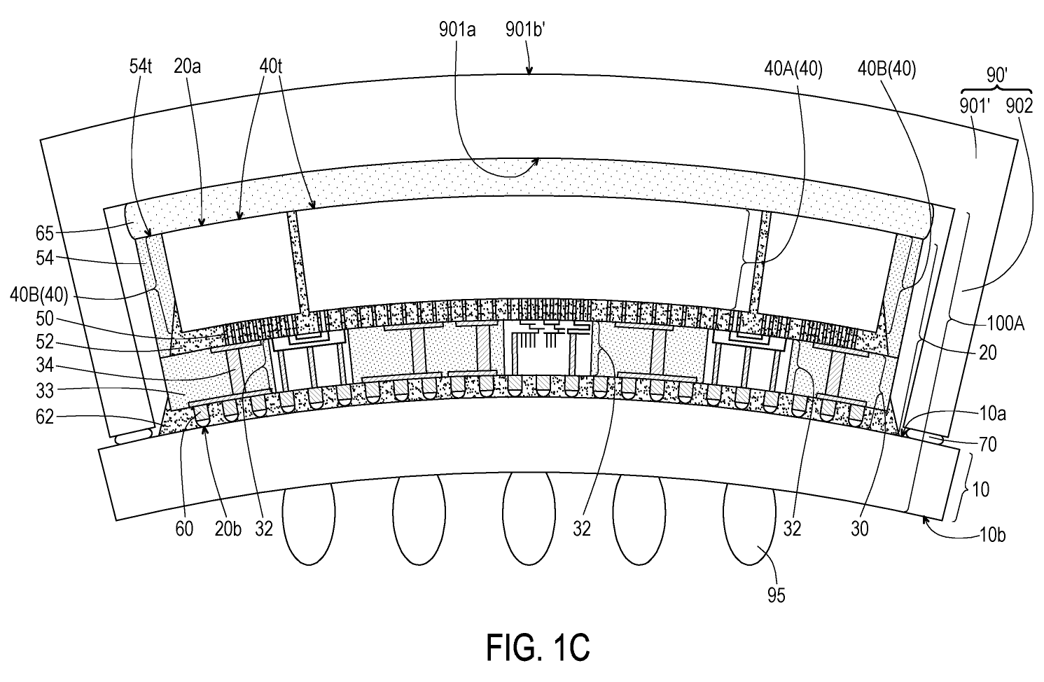

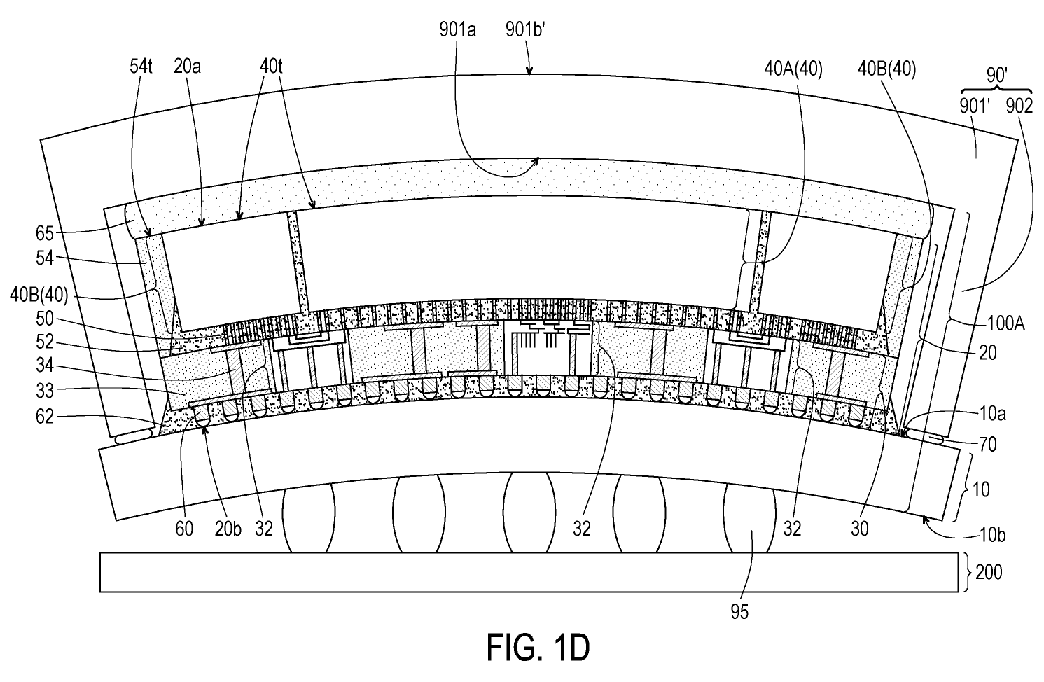

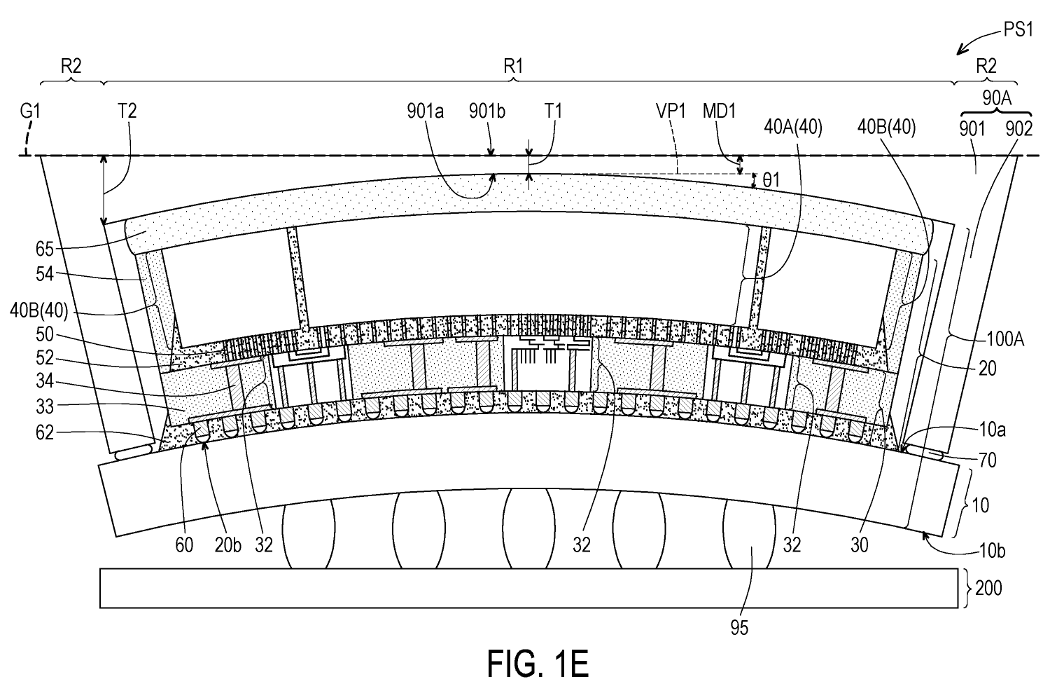

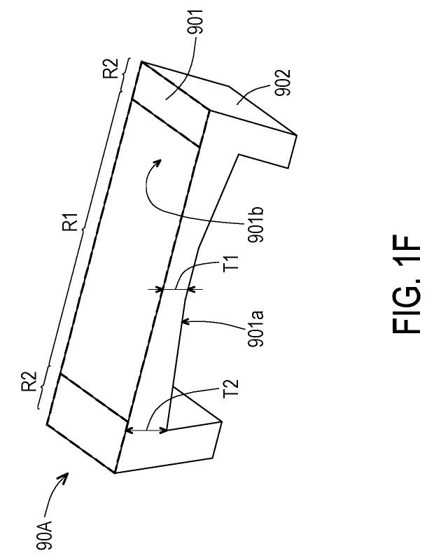

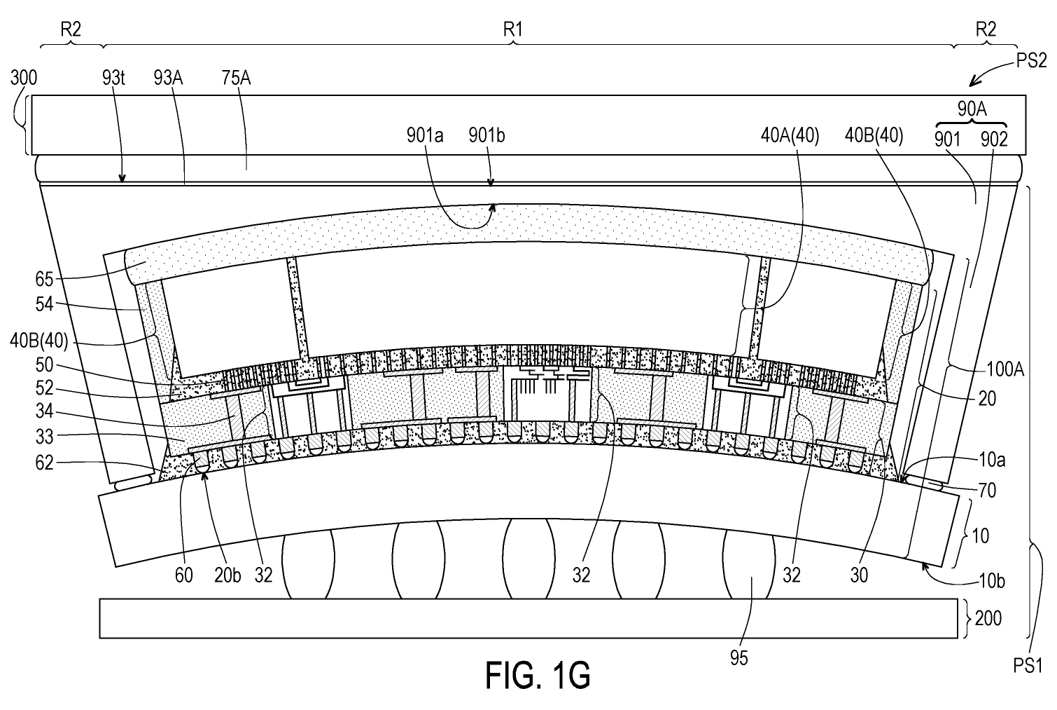

FIGS. 1A-1E are schematic cross-sectional views of various stages of manufacturing a package structure, in accordance with some embodiments. It is understood that additional operations can be provided before, during, and after processes shown by FIGS. 1A-1E, and some of the operations described below can be replaced or eliminated, for additional embodiments of the method. The order of the operations/processes may be interchangeable. FIG. 1F is a schematic perspective view of a lid of a package structure and FIG. 1G is a schematic cross-sectional view of a package assembly, in accordance with some embodiments.

Referring to FIG. 1A, a packaged device 100A including a substrate 10 and a semiconductor package 20 placed on the substrate 10 may be provided. Because there is a coefficient of thermal expansion (CTE) mismatch between the semiconductor package 20 and the substrate 10, the warpage of the packaged device 100A may occur. In some embodiments, the packaged device 100A is bowed and becomes convex (so called crying-shape). The substrate 10 may be a cored package substrate including a core layer, or may be a core-less package substrate that does not have a core layer therein. Alternatively, the substrate 10 is an interposer wafer, a circuit board, a reconstructed wafer, or the like. In some embodiments, the substrate 10 is free from (or includes) active devices such as transistors and diodes therein. In some embodiments, the substrate 10 is also free from (or includes) passive devices such as capacitors, inductors, resistors, or the like therein.

In some embodiments, the substrate 10 includes a plurality of dielectric layers (not specifically shown). For example, the dielectric layers of the substrate 10 includes a core dielectric layer, and an upper dielectric layer and a lower dielectric layer respectively over and under the core dielectric layer. In some embodiments, the upper and lower dielectric layers are formed of dry films such as Ajinomoto Build-up Films (ABFs). In alternative embodiments, the upper and lower dielectric layers are formed of or include polybenzoxazole (PBO), polyimide, benzocyclobutene (BCB), or the like. In some embodiments, the core dielectric layer is formed of epoxy, resin, glass fiber, prepreg (which comprises epoxy, resin, and/or glass fiber), glass, molding compound, plastic, combinations thereof, and/or multi-layers thereof. In alternative embodiments, the core dielectric layer is formed of polymers such as PBO, polyimide, BCB, or the like. The core dielectric layer may include a redistribution structure such as metal lines/pads and vias, which are functioned as through-substrate connection.

With continued reference to FIG. 1A, the substrate 10 may include a first side 10a and a second side 10b opposite to the first side 10a, and the semiconductor package 20 may be coupled to the first side 10a of the substrate 10. The first side 10a may be referred to as a chip-side, while the second side 10b may be referred to a board-side. In some embodiments, the semiconductor package 20 includes device dies and may include other package components (e.g., interposers, packages, die stacks, or the like). For example, the semiconductor package 20 includes one or more package component(s) 30 and one or more semiconductor dies 40 stacked over the package component 30. In some embodiments, the package component 30 is an interposer that includes one or more interconnect die(s) 32, an insulating layer 33 laterally covering the interconnect dies 32, and through vias 34 penetrating through the insulating layer 33. The interconnect dies 32 may be electrically coupled to the semiconductor dies 40A and/or 40B. The interconnect dies 32 may be, independently, an electrical and/or optical input/output (I/O) interface die, an integrated passives die (IPD), a local silicon interconnect die (LSI) with or without deep trench capacitor (DTC) features, a local silicon interconnect die with multi-tier functions such as electrical and/or optical network circuit interfaces, or the like. The types of the interconnect dies 32 may be selected and designated based on the demand and design requirement, and thus are limited in the disclosure. In some embodiments, the interconnect dies 32 are electrically coupled to the through vias 34 through one or more conductive patterns (not individually labeled). It is understood that the structure of the package component 30 shown in FIG. 1 is merely an example, and the details may not be shown.

With continued reference to FIG. 1A, the semiconductor dies 40A and 40B may be bonded to the underlying package component 30. In some embodiments, one semiconductor die 40A and two semiconductor dis 40B are bonded to the same package component 30. However, any number of the semiconductor dies 40A and/or 40B may be bonded to one package component 30, and can be in any arrangement. In some embodiments, the semiconductor dies 40A and 40B are different types of dies, and are collectively referred to as the semiconductor dies 40. In some embodiments, each of the semiconductor dies 40 includes a device die, a package with a device die(s) packaged therein, a System-on-Chip (SoC) die including a plurality of integrated circuits (or device dies) integrated as a system, or the like. The semiconductor dies 40 may be or include logic dies, memory dies, input-output dies, or the like, or combinations thereof. For example, the logic dies include Central Processing Unit (CPU) dies, Graphic Processing Unit (GPU) dies, mobile application dies, Micro Control Unit (MCU) dies, BaseBand (BB) dies, Application processor (AP) dies, or the like. The memory dies may include Static Random Access Memory (SRAM) dies, Dynamic Random Access Memory (DRAM) dies, memory stacks (e.g., High-Performance Memory (HBM) stacks), or the like.

With continued reference to FIG. 1A, the semiconductor dies 40 may be bonded to the underlying package component 30, e.g., through die connectors 50. The die connectors 50 may include micro-bumps, metal pillars with or without caps, controlled collapse chip connection (C4) bumps, or the like. In some embodiments, an underfill 52 is dispensed between the semiconductor dies 40 and the underlying package component 30. For example, the semiconductor dies 40 are bonded to the package component 30 through a Chip-on-Wafer (CoW) bonding process. The semiconductor dies 40, which are discrete chips/packages, may be bonded to the package components 30 that are in an unsawed wafer to form a reconstructed wafer. After the dispensing of the underfills 52, an encapsulant 54, such as a molding compound, may be applied to cover the semiconductor dies 40. A planarization process may then be performed on the encapsulant 54 to level a top surface of the encapsulant 54 with top surfaces of the semiconductor dies 40. A reconstructed wafer is thus formed, and may then be sawed apart to form the discrete semiconductor package 20.

In some embodiments, the semiconductor package 20 is bonded to the substrate 10 through package connectors 60 underlying and joined to the interposer 30. For example, the package connectors 60 are reflowed after the placement of the semiconductor package 20 onto the substrate 10. In some embodiments, the package connectors 60 include micro-bumps, metal pillars with or without caps, C4 bumps, or the like. However, other suitable bonding schemes may also be used for bonding the package component 30 to the substrate 10. An underfill 62 is optionally formed in the gap between the semiconductor package 20 and the substrate 10 to surround the respective package connector 60.

With continued reference to FIG. 1A, one or more adhesive(s) 70 may be formed on the first side 10a of the substrate 10 and may surround the semiconductor package 20. In some embodiments, a material of the adhesive 70 includes a silicone-based adhesive, an epoxy resin-based adhesive, a thermally conductive adhesive, or the like, or may include rubber based-content with curing promoting material. However, other suitable materials may be used for the adhesive 70. In some embodiments, the adhesive 70 is dispensed as a ring encircling the semiconductor package 20, or is dispensed as discrete portions along the edge of the substrate 10.

Still referring to FIG. 1A,, a Thermal Interface Material (TIM) 65 may be formed on a first side 20a of the semiconductor package 20, where the first side 20a is opposite to a second side 20b which is coupled to the package component 30. The TIM 65 may be in physical contact with the first side 20a of the semiconductor package 20 (e.g., the back surfaces 40t of the semiconductor dies 40A and 40B and the surface 54t of the encapsulant 54). The TIM 65 may have a low bulk thermal impedance and high thermal conductivity. For example, the TIM 65 includes a thermal paste, a thermal adhesive, a thermal gap filler, a thermal pad, a thermal tape, a graphite TIM, a carbon nanotube TIM, etc. Other types of TIMs are within the contemplated scope of this disclosure.

Referring to FIG. 1B and with reference to FIG. 1A, a lid 90’ may be disposed on the TIM 65 and may provide a cover for the packaged device 100A. The lid 90’ may contact at least a portion of the TIM 65. The lid 90’ may include a plate portion 901’ that may cover the packaged device 100A. A bottom surface 901a of the plate portion 901’ may extend across most of the plate portion 901’ and contact the TIM 65. The lid 90’ may include a foot portion 902 that may extend from the plate portion 901’ (e.g., in the z direction) and may connect the lid 90’ to the substrate 10 by the adhesive 70. The adhesive 70 may fix the foot portion 902 of the lid 90’ to the substrate 10. In some embodiments, the foot portion 902 and the plate portion 901’ are integrally formed as one-piece. In alternative embodiments, the foot portion 902 and the plate portion 901’ are discrete components and adhered together. The material of the lid 90’ may be or include copper, aluminum, gold, steel, stainless steel, metal alloy, ceramic, polymer material, combinations thereof, and/or other suitable material(s) having high thermal conductivities.

In some embodiments, the lid 90’ is bowed, arched, or curved with one or more curvatures corresponding to the warpage of the packaged device 100A after the lid 90’ is attached to the packaged device 100A. For example, the packaged device 100A has a first warpage level and the lid 90’ has a second warpage level that is substantially in conformity with the first warpage level. In the illustrated embodiment, the plate portion 901’ of the lid 90’ is bowed and becomes convex (crying-shape). The bottom surface 901a of the plate portion 901’ may be bent with one or more curvatures corresponding to the warpage of the packaged device 100A. At this stage, the geometric shape of the top surface 901b’ of the plate portion 901’ may correspond and substantially conform to the bottom surface 901a of the plate portion 901’.

Referring to FIGS. 1C-1D and with reference to FIG. 1B, once the lid 90’ is attached to the packaged device 100A, a plurality of conductive terminals 95 may be formed at the second side 10b of the substrate 10. For example, the conductive terminals 95 includes C4 bumps, metal pillars, electroless nickel-electroless palladium-immersion gold technique (ENEPIG) formed bumps, solder balls, ball-grid-array (BGA) connectors, and/or the like. The conductive terminals 95 may then be disposed on and reflowed to be coupled to a device component 200. The conductive terminals 95 may be used to electrically connect the packaged device 100A (e.g., CoWoS structure) to the device component 200. The device component 200 may be a multiple-layered circuit board (e.g., a printed circuit board (PCB), a mother board, etc.) or other types of device components of an electrical system depending on product requirements.

Referring to FIGS. 1E-1F and with reference to FIG. 1D, a planarization process G1 may be performed on the lid 90’ to form a package structure PS1. The planarization process may include a grinding process, a chemical mechanical polishing (CMP) process, an etching process, a dry polishing process, one or more other applicable processes, or a combination thereof. In some embodiments, the entirety of the top surface 901b’ of the lid 90’ is ground during the planarization process G1. For example, after the planarization process G1, the lid 90A including the planarized top surface 901b is formed. The planarized top surface 901b may be flatter than the bottom surface 901a. In other words, the bottom surface 901a may be more curved than the planarized top surface 901b. The profile of the bottom surface 901a may depend on the warpage of the packaged device 100A. For example, the bottom surface 901a is a multi-curvature surface. The planarized top surface 901b may have a radius of curvature greater than a radius of curvature of any portion of the bottom surface 901a. In some embodiments, assuming a virtual (horizontal) plane VP1 is substantially parallel with the planarized top surface 901b, the virtual plane VP1 and the planarized top surface 901b do not intersect, and every point on the planarized top surface 901 is located at the same (or minimum) distance MD1 from the virtual plane VP1. The virtual plane VP1 may be intersected with the bottom surface 901a, an acute angle θ1 is formed between the virtual plane VP1 and a tangent plane of the bottom surface 901a. The different regions of the bottom surface 901a may include different tangent planes that are not the same plane. It is appreciated that the bending of the structure can cause reliability issues. By performing the planarization process G1 prior to the attachment of the heat-dissipating component (see FIG. 1G), the flatness and the morphology of the top surface of lid may be controlled and the reliability issues caused by the warpage may be reduced/eliminated. The planarized top surface 901b may facilitate the dissipation of heat generated from the semiconductor dies 40A and 40B during operation as will be described later in accompanying with FIG. 1G.

As shown in FIGS. 1E and FIG. 1F, the bottom surface 901a has a crying cross-sectional profile and the planarized top surface 901b is relatively flat. This renders the plate portion 901 of the lid 90A having changing thicknesses. For example, the plate portion 901 has the minimum thickness T1 at the first region R1 of the plate portion 901 and the maximum thickness T2 at the second region R2 of the plate portion 901. The first region R1 may correspond to the central region of the plate portion 901, while the second region R2 may correspond to the peripheral region of the plate portion 901 including the edge and the corner of the lid 90A. For example, the thickness of the plate portion 901 in the first region R1 gradually increases from the center of the first region R1 toward the boundary of the first region R1. However, the change of thickness of the plate portion 901 in the first region R1 may be different than shown depending on the warpage profile of the of the packaged device 100A. In some embodiments, the minimum thickness T1 is in a range of about 1.5 mm and about 3 mm. The maximum thickness T2 is thicker than the minimum thickness T1, and the difference between the maximum thickness T2 and the minimum thickness T1 may be in a range of about 200 μm and about 400 μm. The ratio of the maximum thickness T2 to the minimum thickness T1 may be in a range of about 1.01 and 1.25.

Referring to FIG. 1G and with reference to FIG. 1E, a heat-dissipating component 300 may be attached to the lid 90A through a TIM 75A to form a package assembly PS2. The heat-dissipating component 300 may be a heat sink, a heat spreader, or the like. The TIM 75A may be or include a metal TIM, such as indium foil, phase change liquid metal pad, liquid metal, phase change gel, or the like. In some embodiments, the TIM 75A includes a base material and filler particles mixed in the base material. The base material may be a polymer-based material, an epoxy-based material, a resin-based material, or the like. The filler particles may include thermal conductive material such as diamond, boron nitride, alumina, silica, the like, or a combination thereof. The dimension of the filler particles may be less than 20 µm or even less than 10 µm.

The TIM 75A may be formed on the planarized top surface 901b of the lid 90A. The planarization of the lid to form the planarized top surface 901b may provide a highly uniform bond-line thickness (BLT) control for the interface between the heat-dissipating component 300 and the package structure PS1. For example, the BLT of the TIM 75A corresponding to the first and second regions R1 and R2 of the lid 90A is less than about 50 µm. The TIM 75A may have a uniform thickness across the planarized top surface 901b of the lid 90A after the attaching the heat-dissipating component 300 to the package structure 100A. By planarizing the lid before forming the TIM 75A, a greater amount of the filler particles with finer dimension may be included in the TIM 75A, thereby achieving better effective thermal conductivity (e.g., greater than 20 W/mK). The TIM 75A may achieve a uniform thickness after the thermal process. Depending on the material selection (it should have good thermal conductivity) of the TIM 75A, the lower thermal resistance between the lid 90A and the heat-dissipating component 300 may be achieved. Due to the uniformity and stability of the BLT, delamination of the TIM 75A and deformation of the BLT during the thermal process or during the operation may be reduced. The junction temperature of the package structure 100A may be reduced by about 5 °C to 10 °C, thereby providing improved temperature uniformity or heat spreading performance. The resulting package assembly PS2 may obtain increased power gain by about 8% to about 13%, such as greater than about 10%. The higher thermal design power (TDP) requirements of the hot spots in the resulting structure may be gained by about 25% to about 40%.

In some embodiments, after the planarization process G1, a surface finishing layer 93A is formed on the planarized top surface 901b of the lid 90A. The surface finishing layer 93A may serve to prevent oxidation of the lid 90A. For example, the surface finishing layer 93A is formed of one or more metallic material(s) such as nickel, palladium, platinum, vanadium, gold, alloy thereof, and/or the like. In some embodiments, the surface finishing layer 93A is formed by nickel coating and the top surface 93t of the surface finishing layer 93A has a roughness (Ra) of about 1 μm or less than 1 μm. In some other embodiments, the surface finishing layer 93A includes multiple metallic sublayers and is referred to as a back side metallization (BSM) layer. The BSM layer may include the roughness (Ra) of the top surface 93t being in a range of about 2.5 μm or less. In some embodiments, after forming the surface finishing layer 93A on the planarized top surface 901b of the lid 90A, the TIM 75A is formed on the surface finishing layer 93A, and then the heat-dissipating component 300 is attached to the TIM 75A.

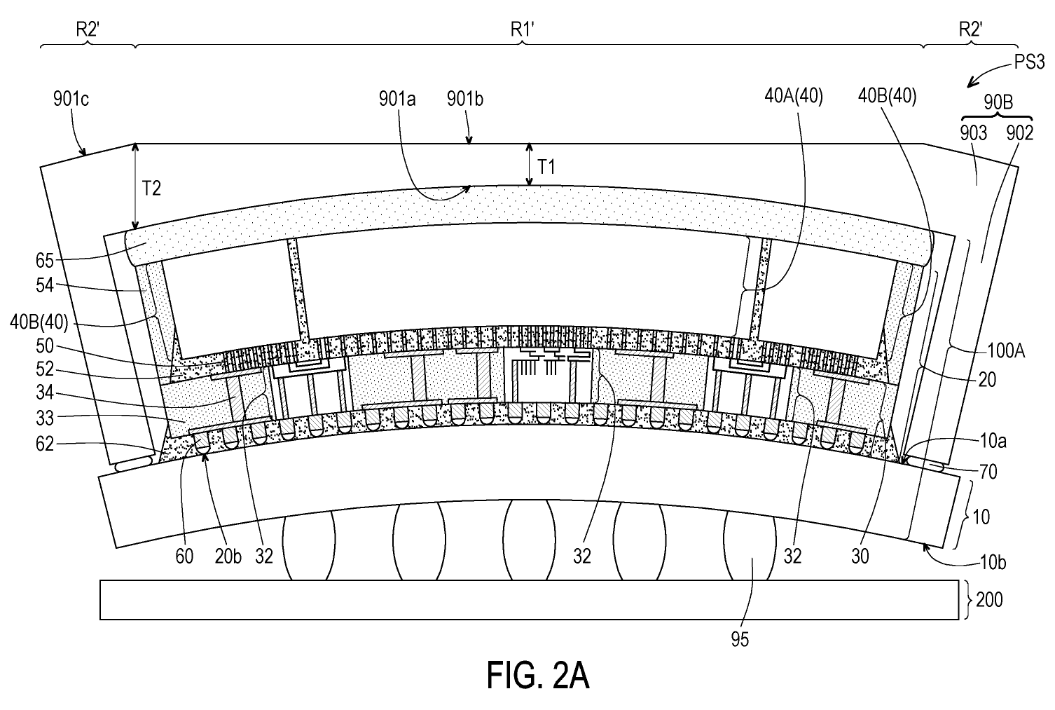

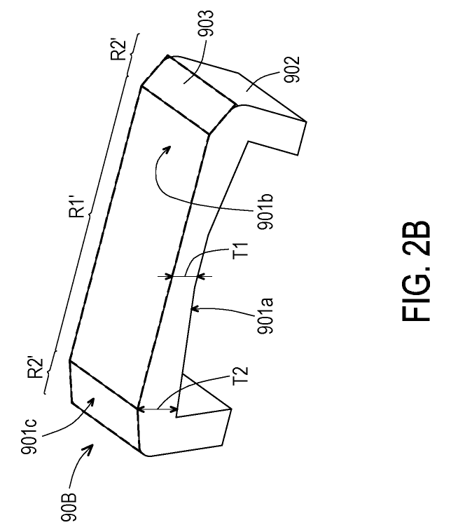

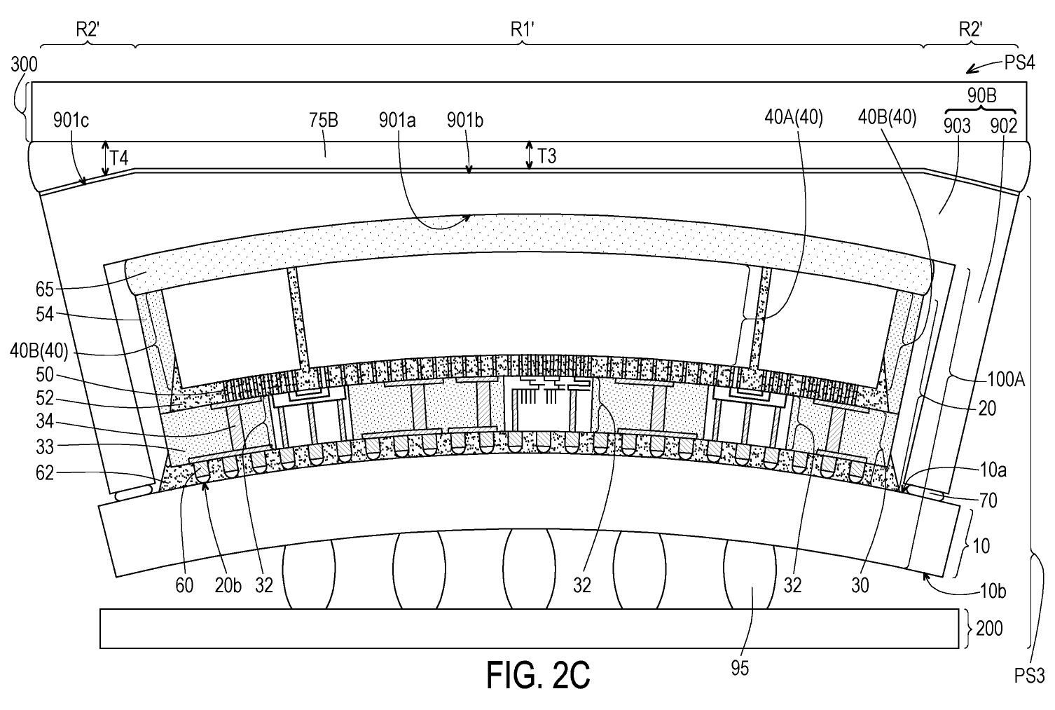

FIG. 2A is a schematic cross-sectional view of a package structure PS3, FIG. 2B is a schematic perspective view of a lid 90B, and FIG. 2C is a schematic cross-sectional view of a package assembly PS4, in accordance with some embodiments.

Referring to FIGS. 2A-2B and with reference to FIGS. 1E-1F, the package structure PS3 may be similar to the package structure PS1, except for the shape of the top side of the lid 90B. For example, the plate portion 903 of the lid 90B includes the planarized top surface 901b and curved (or tilt) surface 901c connected to the planarized top surface 901b, where the planarized top surface 901b corresponds to the first region R1’ and the curved surface 901c corresponds to the second region R2’. The lid 90B may be formed by partially planarizing the top surface of the lid before or after mounting the conductive terminals 95 onto the device component 200. For example, the planarization process is only performed on the first region R1’ to render the planarized top surface 901b, and the second region R2’ is not planarized so that the curved surface 901c remains in the second region R2’.

The plate portion 903 of the lid 90B may have the minimum thickness T1 at the first region R1’ and the maximum thickness T2 at the second region R2’. The first region R1’ may correspond to the central region of the plate portion 903, while the second region R2’ may correspond to the peripheral region of the plate portion 903. The first region R1’ may be directly above the semiconductor package 20 (e.g., the semiconductor dies 40A, and 40B). In some embodiments, the first region R1’ has a same top-view size and a top-view area as the corresponding underlying semiconductor package 20. For example, the first region R1’ fully (or partially) overlaps the semiconductor package 20 in the top view. The ratio of the area of the first region R1’ to the area of the first side 20a of the semiconductor package 20 may be about 0.8 or over 0.8 (e.g., 1, 1.2, or other suitable values).

Referring to FIG. 2C and with reference to FIGS. 2B and 1G, the package assembly PS4 may be provided by attaching the heat-dissipating component 300 to the package structure PS3 through the TIM 75B. The heat-dissipating component 300 and the TIM 75B may be similar to the heat-dissipating component 300 and the TIM 75A described in FIG. 1G, except that the thickness T4 of the TIM 75B corresponding to the second region R2’ is greater than the thickness T3 of the TIM 75B corresponding to the first region R1’. The thickness T3 of the TIM 75B on the planarized top surface 901b and within the first region R1’ may be substantially uniform. The thickness T4 of the TIM 75B corresponding to the second region R2’ may vary depending on the shape of the curved surface 901c. For example, the thickness T4 of the TIM 75B corresponding to the second region R2’ gradually increases from the point connected to the first region R1 to the point at the edge of the lid 90B. In some embodiments, the surface finishing layer 93B is conformally formed on the lid 90B. For example, the surface finishing layer 93B is formed on the planarized top surface 901b and the curved surface 9021c before forming the TIM 75B. The surface finishing layer 93B may serve to prevent oxidation of the lid 90B. The material of the surface finishing layer 93B and may be similar to the surface finishing layer 93A described in FIG. 1G, and thus the detailed thereof are not repeated herein.

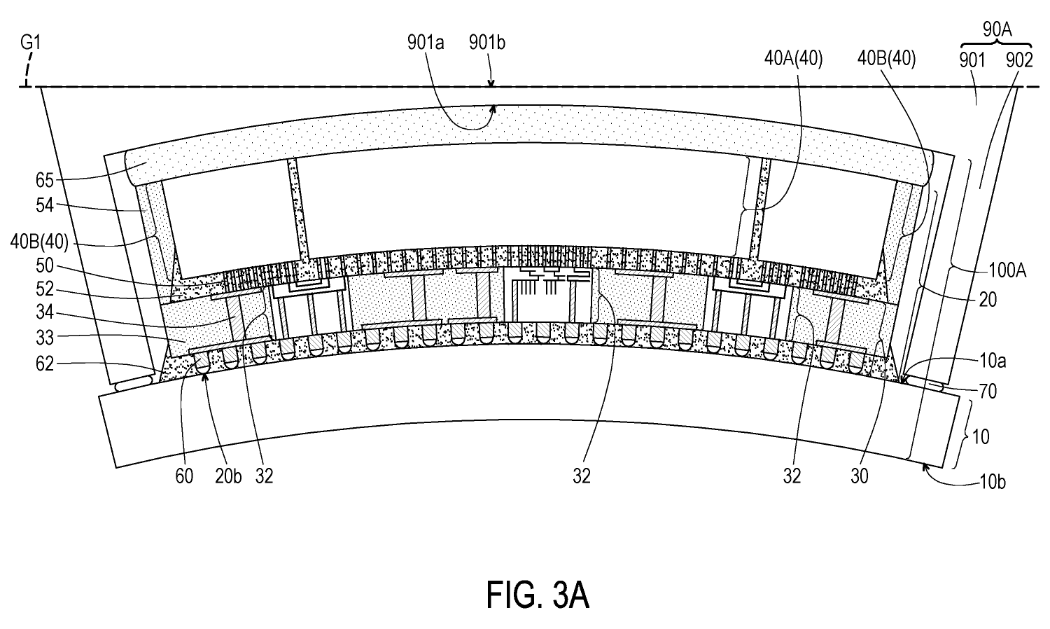

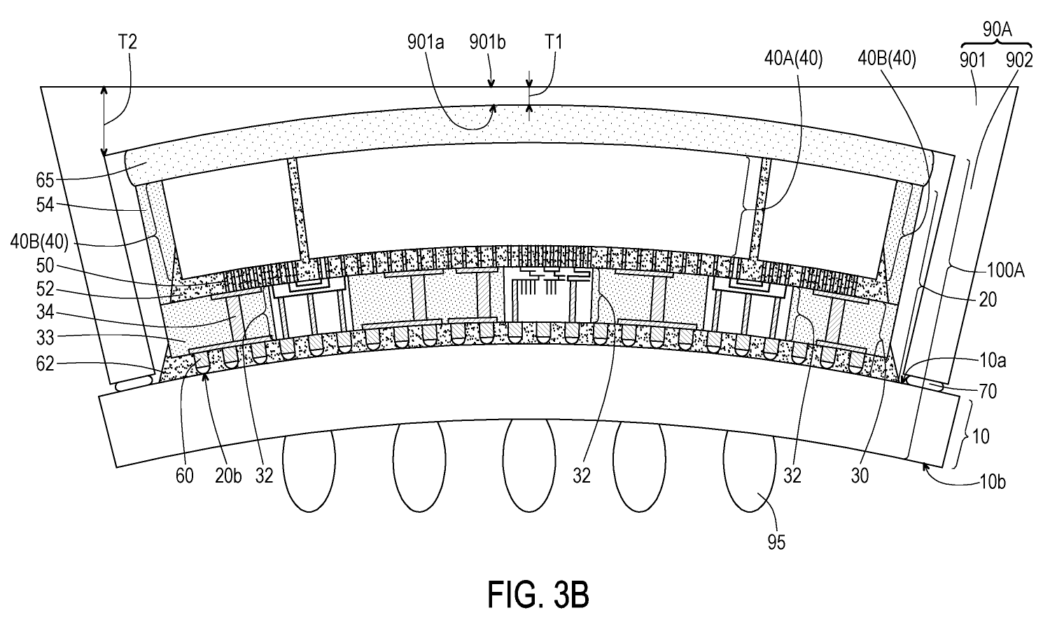

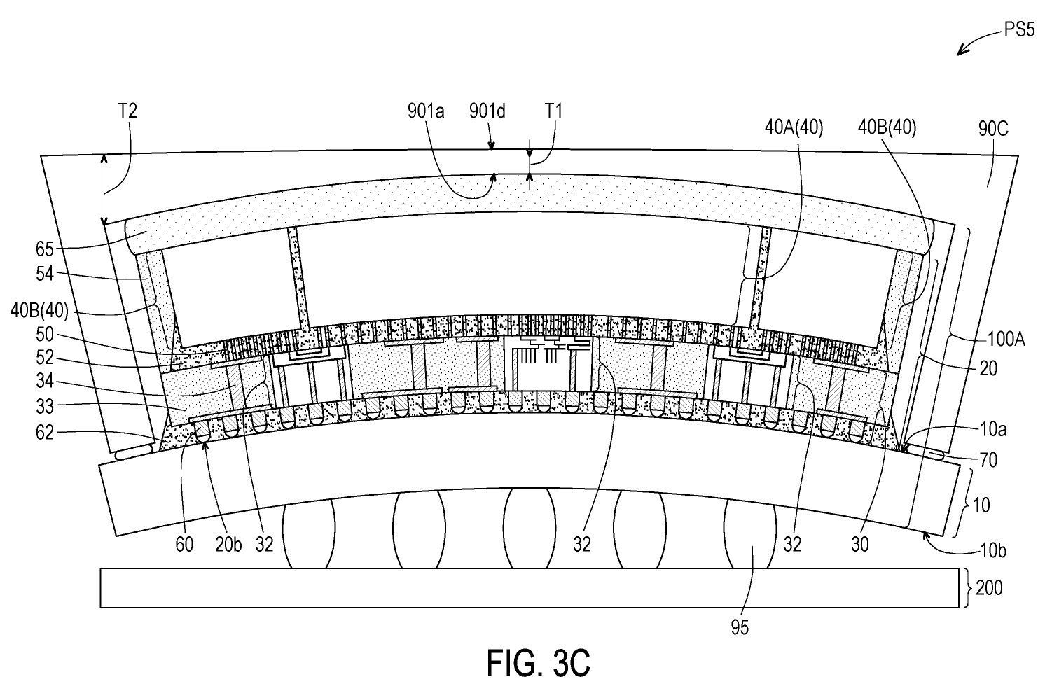

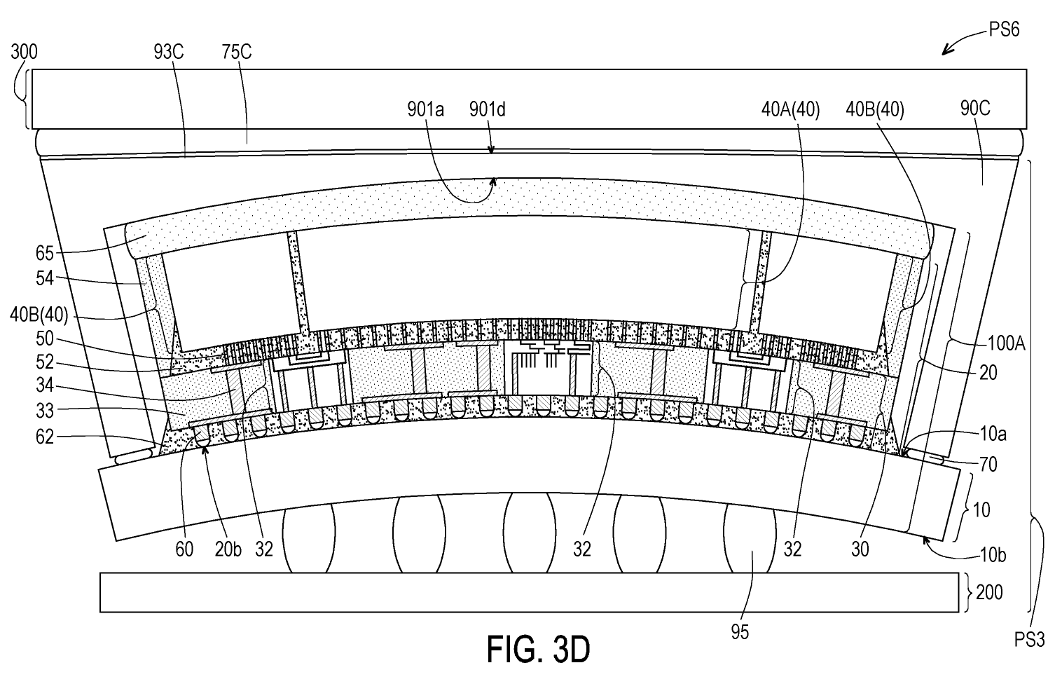

FIGS. 3A-3C are schematic cross-sectional views of various stages of manufacturing a package structure PS5 and FIG. 3D is a schematic cross-sectional view of a package assembly PS6, in accordance with some embodiments.

Referring to FIG. 3A and with reference to FIGS. 1B and 1E, after the lid 90’ is attached to the packaged device 100A through the TIM 65 and the adhesive 70 as described in FIG. 1B, the planarization process G1 may be performed on the top side of the lid 90’ to form the lid 90A having the planarized top surface 901b. The planarization process G1 may be similar to the planarization process G1 described in FIG. 1E, and thus the details thereof are not repeated herein.

Referring to FIGS. 3B-3C and with reference to FIG. 3A and FIGS. 1C-1D, after the planarization process G1, the conductive terminals 95 may be formed on the second side 10b of the substrate 10. The conductive terminals 95 may be similar to the conductive terminals 95 described in FIG. 1C, and thus the details thereof are not repeated herein. Next, the conductive terminals 95 may be disposed on and reflowed to be coupled to the device component 200 so as to form a package structure PS5. The package structure PS5 may exhibit warpage after being subjected to thermal processes such as for coupling the conductive terminals 95 to the device component 200. In some embodiments, during the reflowing of the conductive terminals 95, the top side of the lid 90A may be slightly deformed to form the lid 90C having the top surface 901d. For example, the top surface 901d becomes slightly convex (so called crying-shape). The curvatures of the top surface 901d and the bottom surface 901a of the lid 90C may be different. For example, the radius of curvature of the top surface 901d is greater than the radius of curvature of the bottom surface 901a.

Referring to FIG. 3D and with reference to FIGS. 3C and 1G, the package assembly PS6 may be provided by attaching the heat-dissipating component 300 to the package structure PS5 through the TIM 75C. The heat-dissipating component 300 and the TIM 75C may be similar to the heat-dissipating component 300 and the TIM 75A described in FIG. 1G, except that the BLT of the TIM 75C may be greater than that of the TIM 75A. For example, the BLT of the TIM 75C is in a range of about 50 µm and about 100 µm. In some embodiments, the surface finishing layer 93C is conformally formed on the top surface 901d of the lid 90C before forming the TIM 75C. The surface finishing layer 93C may serve to prevent oxidation of the lid 90C. The material of the surface finishing layer 93C may be similar to the surface finishing layer 93A described in FIG. 1G, and thus the detailed thereof are not repeated herein.

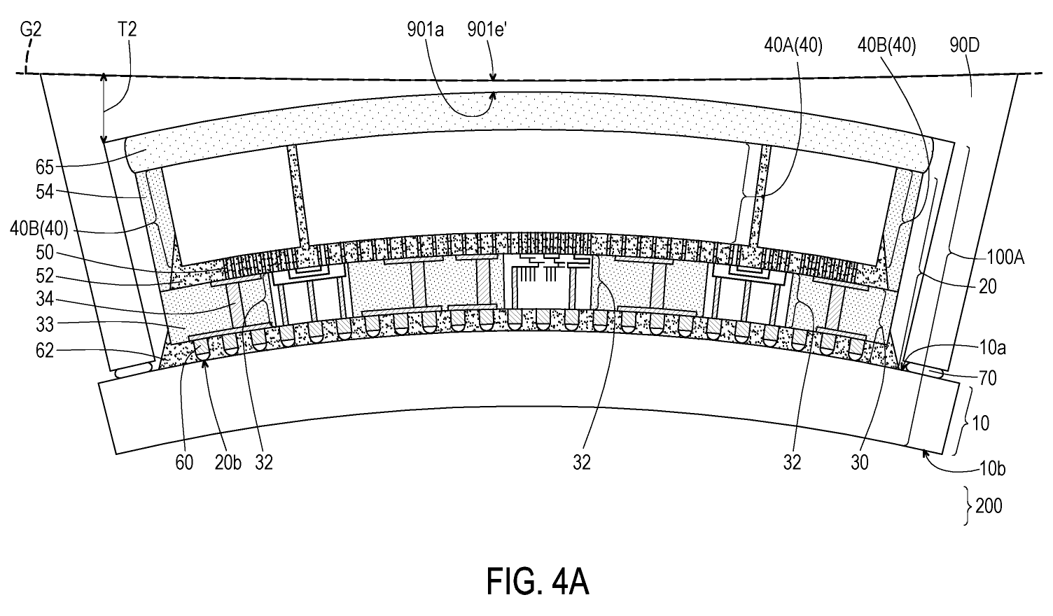

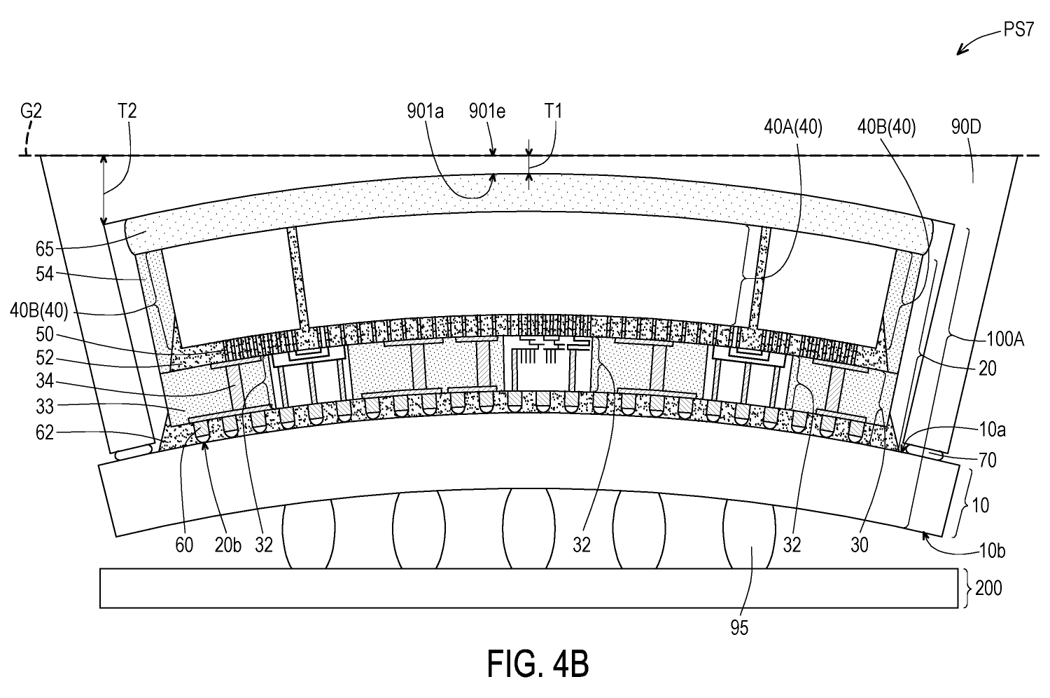

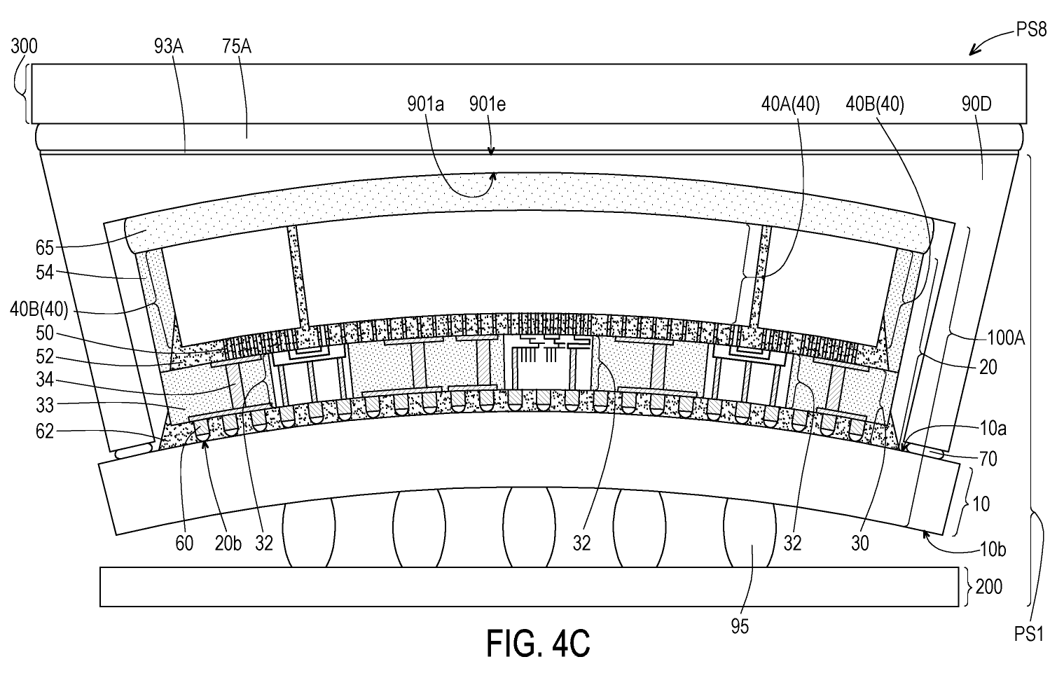

FIGS. 4A-4B are schematic cross-sectional views of various stages of manufacturing a package structure PS7 and FIG. 4C is a schematic cross-sectional view of a package assembly PS8, in accordance with some embodiments.

Referring to FIG. 4A and with reference to FIG. 1B, after the lid 90’ is attached to the packaged device 100A through the TIM 65 and the adhesive 70 as described in FIG. 1B, a planarization process G2 may be performed on the top side of the lid 90’ to form the lid 90D having the top surface 901e’. For example, the top surface 901e’ is a concave surface. In some embodiments, during the planarization process G2, the removed amount of the plate portion in the first region R1” is greater than that of the plate portion in the second region R2” so as to render the concave top surface 901e’.

Referring to FIG. 4B and with reference to FIG. 4A and FIG. 1E, after the planarization process G2, the conductive terminals 95 may be formed on the second side 10b of the substrate 10. The conductive terminals 95 may be similar to the conductive terminals 95 described in FIG. 1C, and thus the details thereof are not repeated herein. Next, the conductive terminals 95 may be disposed on and reflowed to be coupled to the device component 200 so as to form a package structure PS7. In some embodiments, during the reflowing of the conductive terminals 95, the top surface 901e’ of the lid 90D may be slightly deformed. For example, the top side of the lid 90D changes from the concave top surface 901e’ to substantially flat top surface 901e.

Referring to FIG. 4C and with reference to FIGS. 4B and 1G, the package assembly PS8 may be provided by attaching the heat-dissipating component 300 to the package structure PS7 through the TIM 75A. The heat-dissipating component 300 and the TIM 75A may be similar to the elements described in FIG. 1G, and thus the detailed thereof are not repeated herein. The surface finishing layer 93C is optionally formed on the top surface 901e of the lid 90D before forming the TIM 75A to prevent oxidation of the lid 90D. The surface finishing layer 93A may be similar to the element described in FIG. 1G, and thus the detailed thereof are not repeated herein.

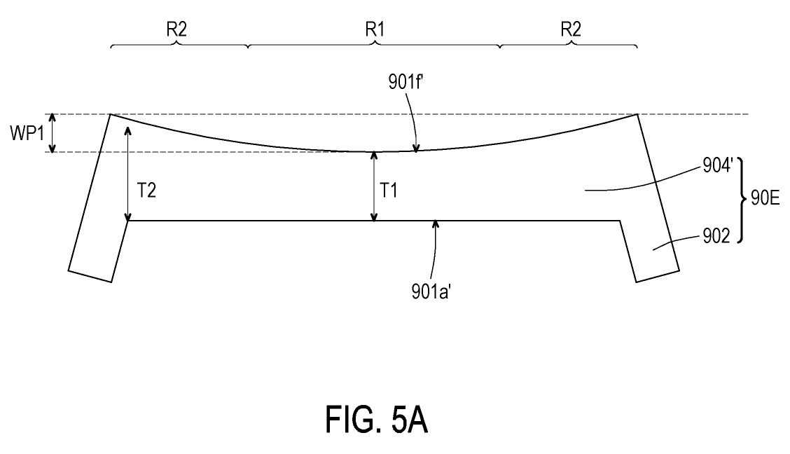

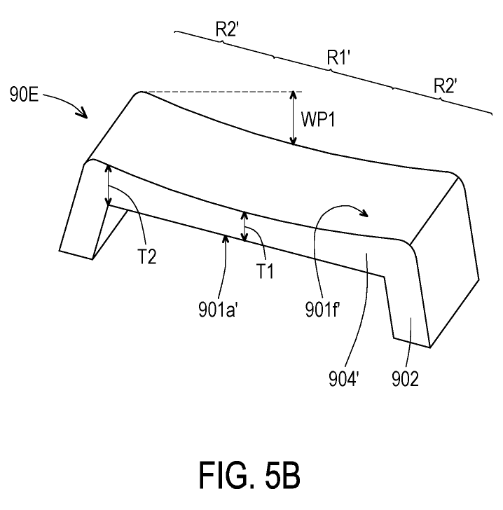

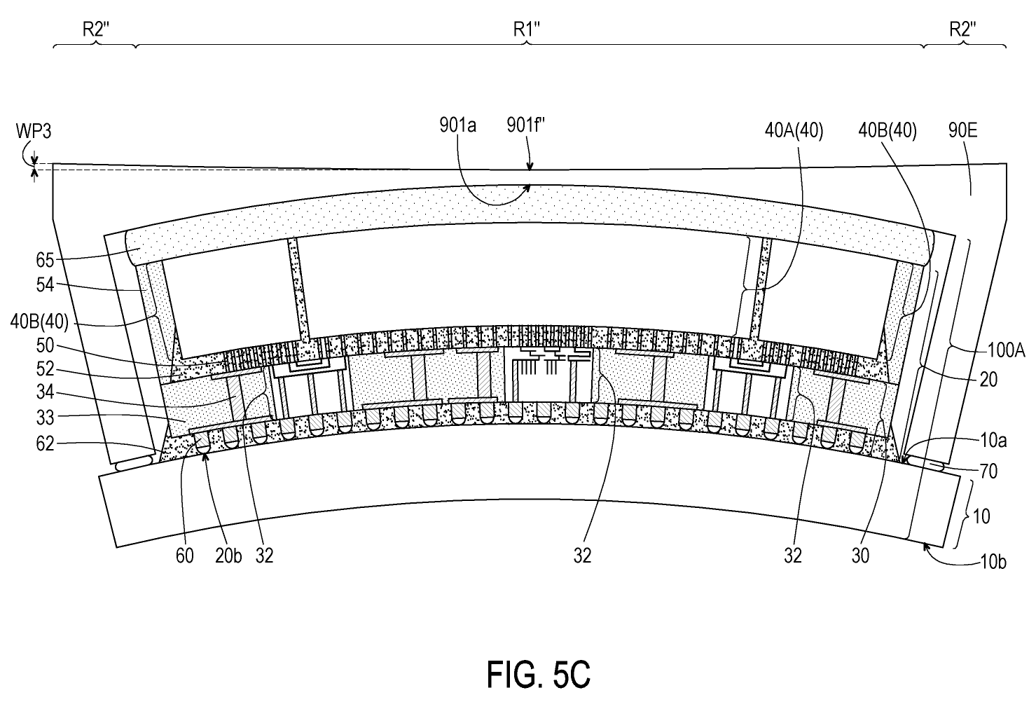

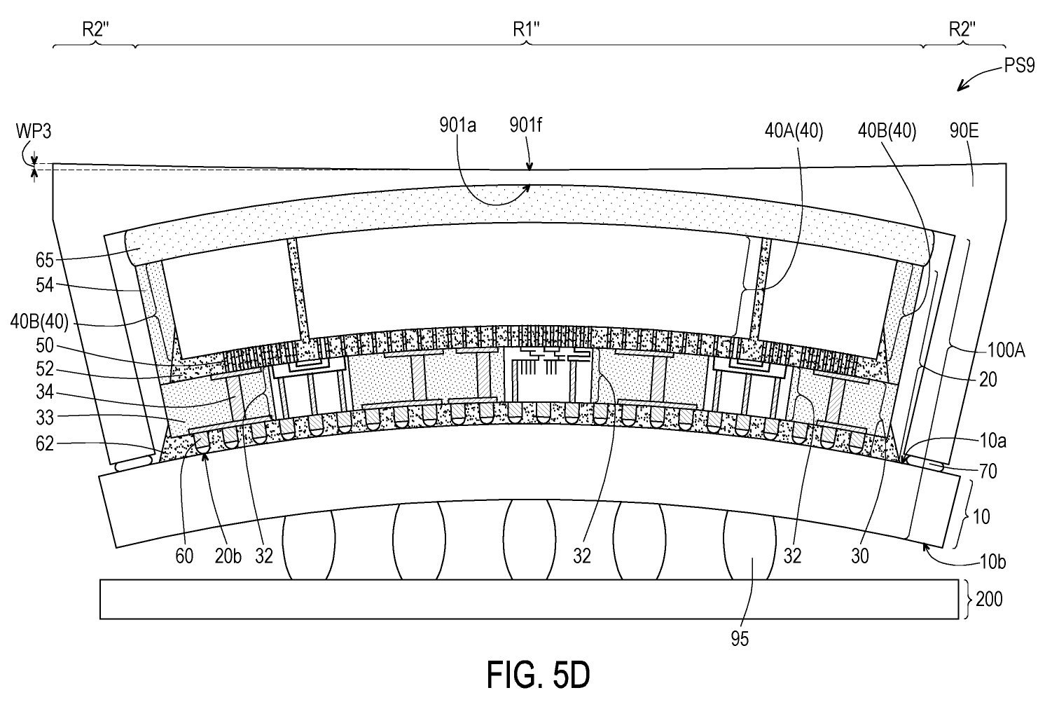

FIGS. 5A-5B are schematic views of a lid 90E and FIGS. 5C-5D are schematic cross-sectional views of various stages of manufacturing a package structure PS9, in accordance with some embodiments.

Referring to FIGS. 5A-5B, the lid 90E may be pre-formed by a stamping process or other suitable process which can make the lid 90E to be bowed and have the concave top side (so called smiling-shape). For example, the lid 90E has a plate portion 904’ and the foot portion 902 connected to the plate portion 904’. The plate portion 904’ may have a top surface 901f’ and a bottom surface 901a’, where the top surface 901f’ has a concave cross-sectional shape and the bottom surface 901a’ may be substantially flat. The material of the lid 90E may be similar to that of the lid 90A described in the previous embodiments.

With continued reference to FIGS. 5A-5B, the top surface 901f’ of the lid 90E may have a smiling cross-sectional profile and the bottom surface 901a’ of the lid 90E may be relatively flat. This renders the plate portion 904’ of the lid 90E having changing thicknesses. For example, the plate portion 904’ has the minimum thickness T1 at the first region R1 of the plate portion 904’ and the maximum thickness T2 at the second region R2 of the plate portion 904’. In some embodiments, the minimum thickness T1 is in a range of about 1.5 mm and about 3 mm. The maximum thickness T2 is thicker than the minimum thickness T1, and the difference between the maximum thickness T2 and the minimum thickness T1 may be in a range of about 200 μm and about 400 μm. The ratio of the maximum thickness T2 to the minimum thickness T1 may be in a range of about 1.01 and 1.25. The height difference WP1 or warpage of the lid 90E may be in a range of about 200 μm and about 500 μm.

Referring to FIGS. 5C-5D and with reference to FIG. 5A, the lid 90E may be attached to the packaged device 100A through the TIM 65 and the adhesive 70. During the attachment, the lid 90E may be deformed. Since the lid 90E is pre-formed to have a concave top surface, the lid 90E bonded to the packaged device 100A may have an inherent stress, which may cause the packaged device 100A to warp against the existing warpage direction, hence compensating for the existing warpage. For example, the top surface 901f’ of the lid 90E is flattened to render the top surface 901f” of the lid 90E. The height difference WP2 or warpage of the lid 90E may be in a range of about 50 μm and about 150 μm. Next, the conductive terminals 95 may be formed on the second side 10b of the substrate 10. The conductive terminals 95 may be similar to the conductive terminals 95 described in FIG. 1C, and thus the details thereof are not repeated herein. The conductive terminals 95 may then be disposed on and reflowed to be coupled to the device component 200 so as to form a package structure PS9.

In some embodiments, during the reflowing of the conductive terminals 95, the top surface 901f” of the lid 90E may be slightly deformed to form the flattened top surface 901f. For example, the flattened top surface 901f and the bottom surface 901a are curved in opposing directions. In some embodiments, the flattened top surface 901f is slightly concave, while the bottom surface 901a is convex. As compared to the top surface 901f” shown in FIG. 5C, the flattened top surface 901f of the lid 90E may be flatter. For example, the height difference WP3 or warpage of the lid 90E of the package structure PS9 may be less than 50 μm.

In some embodiments, the heat-dissipating component (not shown) is attached to the package structure PS9 through the TIM (not shown) to form a package assembly as described in FIG. 4C, and thus the detailed descriptions are not repeated for the sake of brevity. In some embodiments, the surface finishing layer (not shown) is formed on the top surface 901f of the lid 90E before forming the TIM so as to prevent oxidation of the lid 90E. The surface finishing layer may be similar to the element described in FIG. 1G, and thus the detailed thereof are not repeated herein.

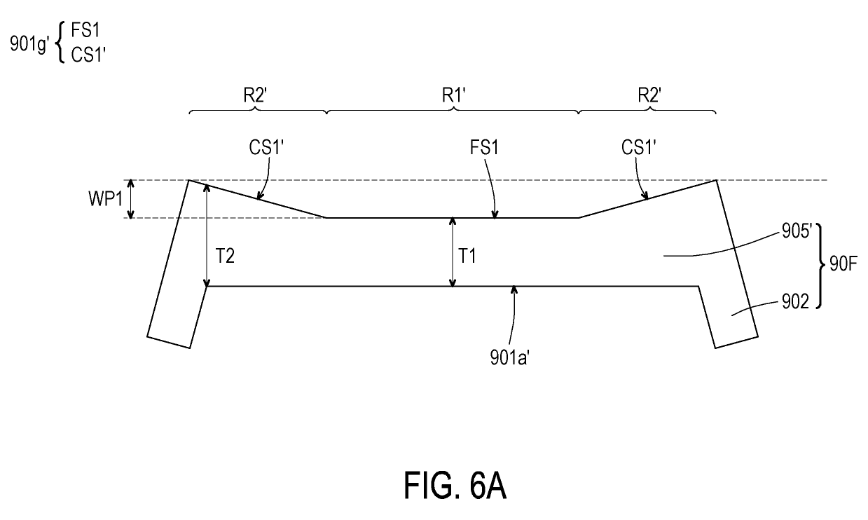

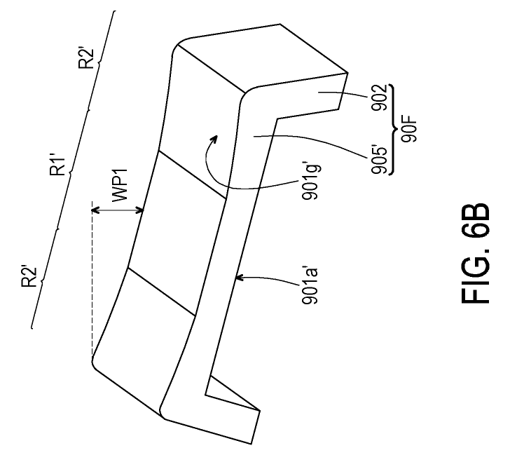

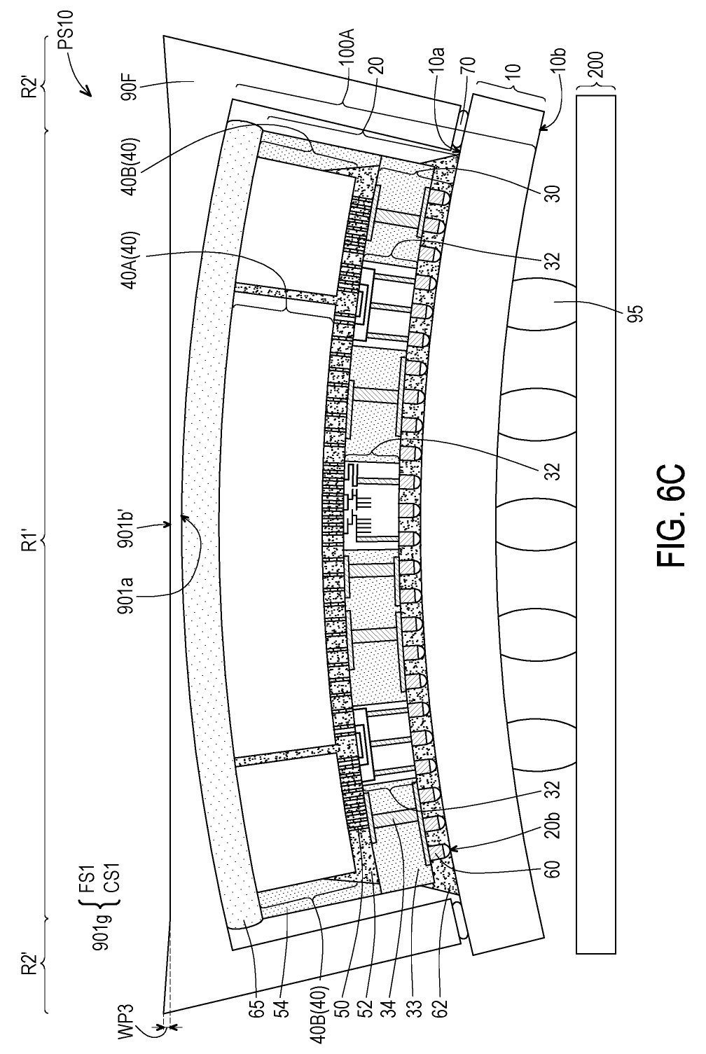

FIGS. 6A-6B are schematic views of a lid 90F and FIG. 6C is a schematic cross-sectional view of a package structure PS10, in accordance with some embodiments.

Referring to FIGS. 6A-6B and with reference to FIGS. 5A-5B, the lid 90F may be similar to as the lid 90E, except that the top surface 901g’ of the plate portion 905’ of the lid 90F includes a substantially flat surface FS1 in the first region R1’ and a curved surface CS1’ in the second region R2’, where the curved surface CS1’ is connected to the substantially flat surface FS1. In some embodiments, the lid 90F is pre-formed by a stamping process or other suitable process which can make the lid 90F to be bowed upwardly and have a portion concave and another portion flat. In alternative embodiments, the lid 90F is provided by planarizing the first region R1 of the lid 90E. In some embodiments, the plate portion 905’ has the minimum thickness T1 at the first region R1’ of the plate portion 905’ and the maximum thickness T2 at the second region R2’ of the plate portion 905’. The minimum thickness T1 may be in a range of about 1.5 mm and about 3 mm. The maximum thickness T2 is thicker than the minimum thickness T1, and the difference between the maximum thickness T2 and the minimum thickness T1 may be in a range of about 200 μm and about 400 μm. The ratio of the maximum thickness T2 to the minimum thickness T1 may be in a range of about 1.01 and 1.25. The height difference WP1 or warpage of the lid 90F may be in a range of about 200 μm and about 500 μm.

Referring to FIG. 6C and with reference to FIGS. 6A, the lid 90F may be attached to the packaged device 100A through the TIM 65 and the adhesive 70. During the attachment, the lid 90F may be deformed. Next, the conductive terminals 95 may be formed on the second side 10b of the substrate 10. The conductive terminals 95 may be similar to the conductive terminals 95 described in FIG. 1C, and thus the details thereof are not repeated herein. The conductive terminals 95 may then be disposed on and reflowed to be coupled to the device component 200 so as to form a package structure PS10. In some embodiments, after coupling the conductive terminals 95 to the device component 200, the top side of the lid 90F is slightly deformed to form the flattened top surface 901g. For example, the curved surface CS1’ in the second region R2’ is flattened to render the flattened surface CS1 of the top surface 901g connected to the substantially flat surface FS1. In some embodiments, the substantially flat surface FS1 is flatter than the flattened surface CS1. The height difference WP3 or warpage of the lid 90F may be less than 50 μm.

In some embodiments, the heat-dissipating component (not shown) is attached to the package structure PS10 through the TIM (not shown) to form a package assembly as described in FIG. 4C, and thus the detailed descriptions are not repeated for the sake of brevity. In some embodiments, the surface finishing layer (not shown) is formed on the top surface 901g of the lid 90F before forming the TIM so as to prevent oxidation of the lid 90F. The surface finishing layer may be similar to the element described in FIG. 1G, and thus the detailed thereof are not repeated herein.

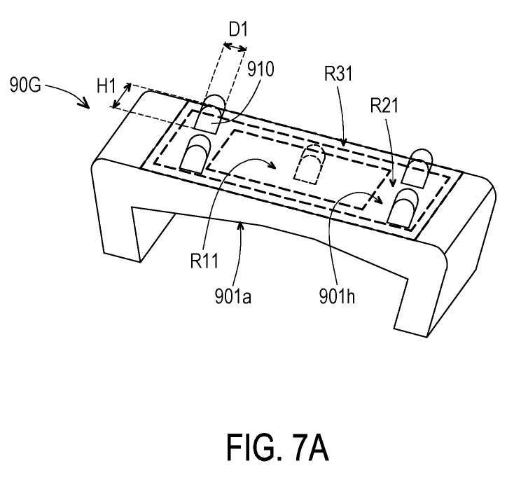

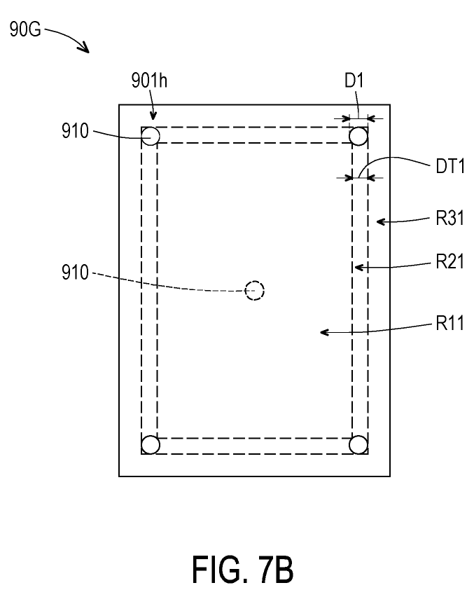

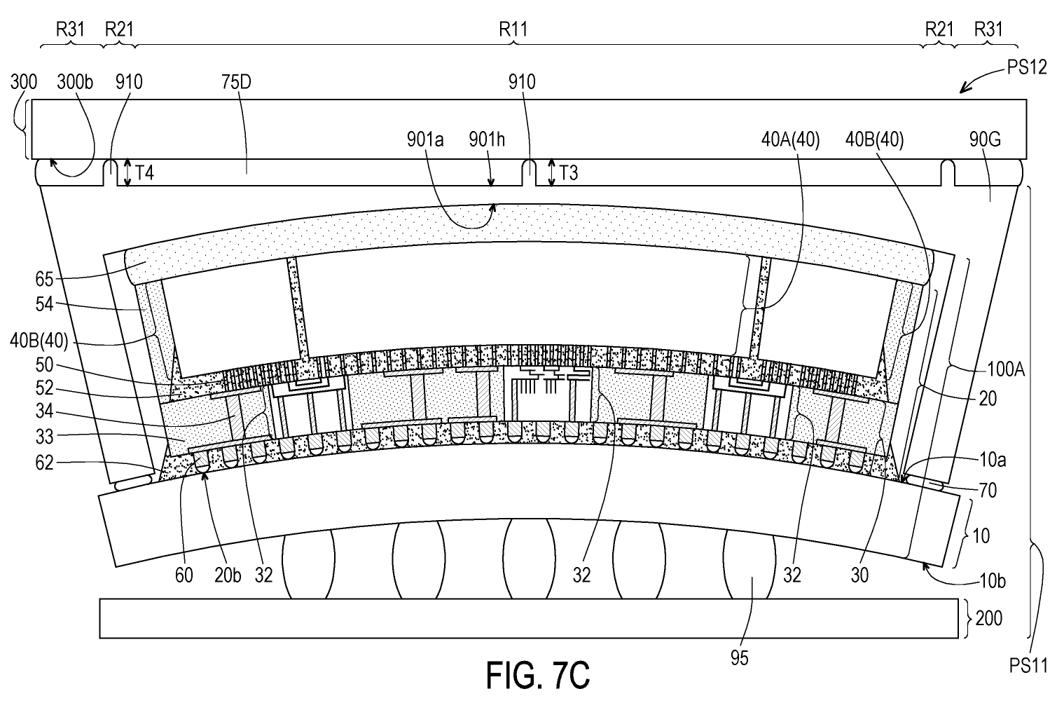

FIGS. 7A-7B are schematic views of a lid 90G and FIG. 7C is a schematic cross-sectional view of a package assembly PS12, in accordance with some embodiments.

Referring to FIGS. 7A-7B and with reference to FIG. 1F, the lid 90G may be similar to the lid 90A described in FIG. 1F, except that the lid 90G includes a plurality of protrusions 910 disposed on the top surface 901h of the lid 90G. In some embodiments, the lid 90G including the protrusions 910 is formed by a stamping process or the like. In alternative embodiments, the protrusions 910 of the lid 90G are formed by plating suitable material(s) on the top side of the lid, partially removing the top side of the lid, etc. For example, the top surface 901h of the lid 90G is divided into three regions: the first region R11, the second region R21, and the third region R31. The first region R11 may be the central region of the lid 90G, the second region R21 may be connected to and enclose (e.g., surround) the first region R11, and the third region R31 may be connected to and enclose (e.g., surround) the second region R21, where the second region R21 is between the first and the third region R31. In some embodiments, at least some of the protrusions 910 are disposed in the second region R21. As shown in FIGS. 7A-7B, four protrusions 910 are disposed at the corners of the second region R21. In some embodiments, some of the protrusions 910 are disposed in the second region R21 and another protrusion(s) 910 may be disposed in the first region R11. The protrusion(s) 910 may or may not be disposed in the third region R31.

With continued reference to FIGS. 7A-7B, the lateral dimension D1 (e.g., the width or the diameter) of the respective protrusion 910 may be greater than 1 mm or 2 mm. The lateral dimension DT1 (e.g., the width) of the second region R21 may be substantially equal to or greater than the lateral dimension D1 of the respective protrusion 910. The height of the respective protrusion 910 may be in a range of about 20 μm and about 50 μm. The top-view shape of the respective protrusion 910 is illustrated as a circle, while any other shape (e.g., a rectangle, a circle, a hexagon, an octagon, a triangle, a polygon, a combination thereof, etc.) may also be used. The protrusions 910 may serve as a stopper to help prevent pump-out of the subsequently-formed TIM as described below.

Referring to FIG. 7C and with reference to FIGS. 7A-7B and FIG. 1G, the lid 90G may be attached to the packaged device 100A through the TIM 65 and the adhesive 70. Next, the conductive terminals 95 may be formed on the second side 10b of the substrate 10. The conductive terminals 95 may then be disposed on and reflowed to be coupled to the device component 200 so as to form a package structure PS11. In some embodiments, the heat-dissipating component 300 is attached to the package structure PS11 through the TIM 75D to form a package assembly PS12. The heat-dissipating component 300 and the TIM 75D may be similar to the heat-dissipating component 300 and the TIM 75A described in FIG. 1G, except that the dimension of the filler particles in the TIM 75D may be about 2 µm or less than 2 µm.

With continued reference to FIG. 7C and FIGS. 7A-7B, the orthogonal projection of the first region R11 may overlap the orthogonal projection of the semiconductor package 20. In some embodiments, one or more protrusion(s) 910 are disposed directly over the semiconductor package 20. The lid 90G may provide superior bond-line thickness and uniformity between the heat-dissipating component 300 and the package structure PS11. For example, the average BLT of the TIM 75D is less than about 50 µm. Due to the uniformity and stability of the BLT, delamination of the TIM 75D and deformation of the BLT during the thermal process or operation may be reduced. The BLT T3 of the TIM 75D in the first region R11 may be less than 50 μm. The portion of the TIM 75D in the second region R21 may be thicker than the portion of the TIM 75D in the first region R11. For example, the difference between the BLT T4 of the TIM 75D in the second region R21 and the BLT T3 of the TIM 75D in the first region R11 may be in a range of about 10 μm and 20 μm.

Still referring to FIG. 7C, during the attachment of the heat-dissipating component 300, the TIM 75D may be compressed between the bottom surface 300b of the heat-dissipating component 300 and the top surface 901h of the lid 90G. During the operation, the warpage level of the package structure 100A may change as the operation temperature increases or decreases, and the change of warpage may cause the TIM 75D to change (or move). By configuring the protrusions 910 on the top surface 901h of the lid 90G to serve as a stopper, the movement of the TIM 75D may be limited by the protrusions 910 so as to prevent pump-out of the TIM 75D. In this manner, the thickness of the TIM 75D may remain substantially uniform and the usable lifetime of the TIM 75D may be extended. The package assembly PS12 having good heat dissipation efficiency and reliability may be obtained.

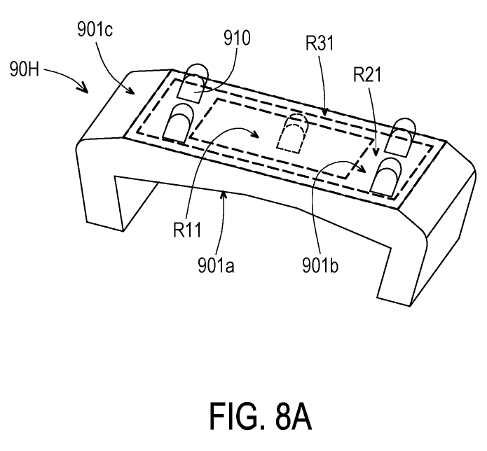

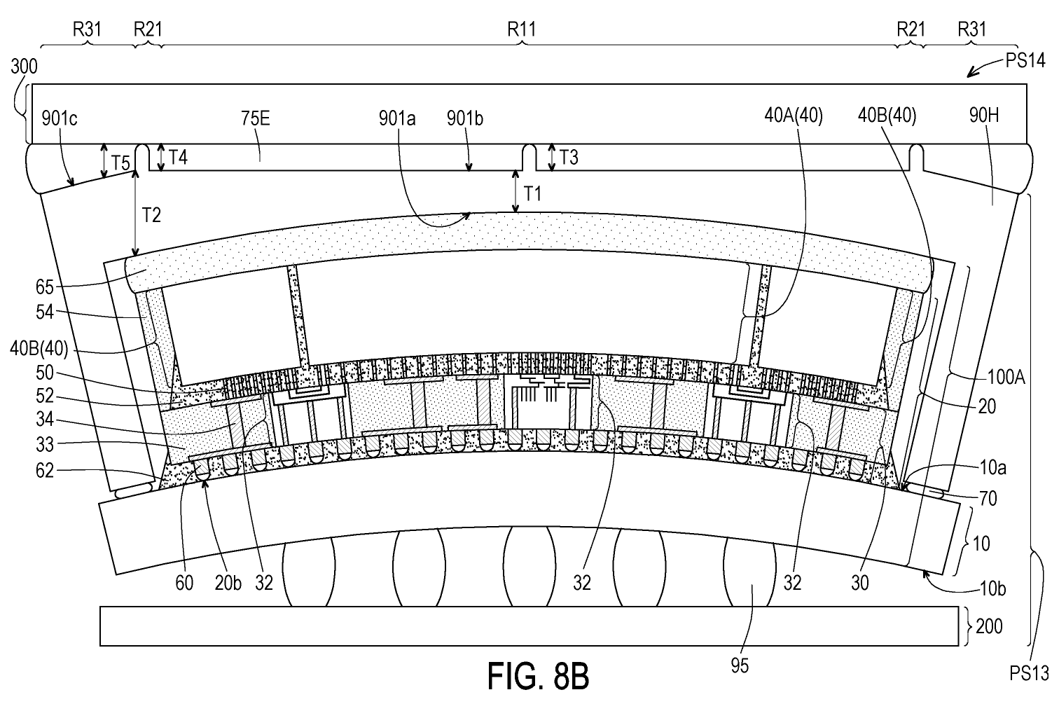

FIG. 8A is a schematic perspective view of a lid 90H and FIG. 8B is a schematic cross-sectional view of a package assembly PS14, in accordance with some embodiments.

Referring to FIG. 8A and with reference to FIG. 7A and FIG. 2B, the lid 90H is similar to the lid 90B described in FIG. 2B, except that the lid 90H further includes a plurality of protrusions 910 disposed on the planarized top surface 901b. In some embodiments, the curved surface 901c of the lid 90H is free of the protrusions 910 disposed thereon. The arrangement, the material, the dimension of the protrusions 910 of the lid 90H may be similar to those of the protrusions 910 described in FIGS. 7A-7B, and thus the detailed descriptions are not repeated herein.

Referring to FIG. 8B and with reference to FIG. 8A and FIG. 7C, the lid 90H may be attached to the packaged device 100A through the TIM 65 and the adhesive 70. Next, the conductive terminals 95 may be formed on the second side 10b of the substrate 10. The conductive terminals 95 may then be disposed on and reflowed to be coupled to the device component 200 so as to form a package structure PS13. In some embodiments, the heat-dissipating component 300 is attached to the package structure PS13 through the TIM 75E to form a package assembly PS14. The heat-dissipating component 300 and the TIM 75E may be similar to the heat-dissipating component 300 and the TIM 75A described in FIG. 1G, except that the dimension of the filler particles in the TIM 75E may be about 2 µm or less than 2 µm.

With continued reference to FIG. 8B, FIG. 8A and FIG. 7C, the orthogonal projection of the first region R11 may overlap the orthogonal projection of the semiconductor package 20. In some embodiments, one or more protrusion(s) 910 are disposed directly over the semiconductor package 20. The lid 90H may provide superior BLT and uniformity between the heat-dissipating component 300 and the package structure PS13. For example, the average BLT of the TIM 75E is less than about 50 µm. The BLT T3 of the TIM 75E in the first region R11 may be less than 50 μm. The portion of the TIM 75E in the second region R21 may be thicker than the portion of the TIM 75E in the first region R11. For example, the difference between the BLT T4 of the TIM 75E in the second region R21 and the BLT T3 of the TIM 75E in the first region R11 may be in a range of about 10 μm and 20 μm. The portion of the TIM 75E in the third region R31 may be thicker than the portion of the TIM 75E in the second region R21. For example, the BLT T5 of the portion of the TIM 75E in the third region R31 is in a range of about 50 μm and 100 μm. By configuring the protrusions 910 on the planarized top surface 901b of the lid 90H to serve as a stopper, the movement of the TIM 75E may be limited by the protrusions 910 so as to prevent pump-out of the TIM 75E. In this manner, the thickness of the TIM 75E may remain substantially uniform and the usable lifetime of the TIM 75E may be extended. The package assembly PS14 having good heat dissipation efficiency and reliability may be obtained.

In accordance with some embodiments, a device includes a semiconductor package including a first side and a second side opposite to each other, a substrate coupled to the second side of the semiconductor package, and a lid coupled to the substrate and the first side of the semiconductor package. The lid includes a first surface and a second surface opposite to each other, the second surface faces the semiconductor package, and the first surface is flatter than the second surface.

In accordance with some embodiments, a device includes a substrate, a semiconductor package disposed on the substrate, and a lid disposed on the substrate. The semiconductor package includes semiconductor dies laterally covered by an encapsulant. The lid includes a plate portion covering the semiconductor package and a foot portion connecting the plate portion to the substrate, and the plate portion includes a varying thickness.

In accordance with some embodiments, a method includes: coupling a semiconductor package to a substrate; attaching a lid to the substrate and the semiconductor package, where the lid includes a top surface and a bottom surface facing the semiconductor package; and flattening the lid, where after flattening the lid, a flattened top surface of the lid is flatter than the bottom surface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a semiconductor package comprising a first side and a second side opposite to each other;
a substrate coupled to the second side of the semiconductor package; and
a lid coupled to the substrate and the first side of the semiconductor package, the lid comprising a first surface and a second surface opposite to each other, the second surface facing the semiconductor package, the first surface being flatter than the second surface.

2. The device of claim 1, wherein the lid comprises a first region and a second region surrounding the first region, the first region overlaps semiconductor dies of the semiconductor package in a top view, and a first thickness of the lid in the first region is less than a second thickness of the lid in the second region.

3. The device of claim 1, further comprising:
a thermal interface material disposed on the first surface of the lid; and
a heat-dissipating component disposed over the lid and thermally coupled to the lid through the thermal interface material.

4. The device of claim 3, wherein the thermal interface material comprises a higher thickness uniformity than the lid.

5. The device of claim 1, wherein the first surface of the lid comprises a flat portion and a curved portion connected to the flat portion, and the flat portion is directly over semiconductor dies of the semiconductor package.

6. The device of claim 1, wherein a radius of curvature of the first surface of the lid is greater than a radius of curvature of the second surface of the lid.

7. The device of claim 1, wherein the first surface and the second surface are curved in opposing directions.

8. The device of claim 1, wherein the lid further comprises:
protrusions disposed on the first surface of the lid.

9. The device of claim 8, wherein the lid comprises a first region and a second region surrounding the first region, the first region overlaps semiconductor dies of the semiconductor package in a top view, and the protrusions of the lid are within the second region.

10. The device of claim 9, wherein the protrusions of the lid are at corners of the second region in the top view.

11. The device of claim 8, wherein the first surface of the lid comprises a flat portion and a curved portion connected to the flat portion, the flat portion is directly over semiconductor dies of the semiconductor package, and the protrusions are disposed on the flat portion.

12. A device, comprising:
a substrate;
a semiconductor package disposed on the substrate, the semiconductor package comprising semiconductor dies laterally covered by an encapsulant; and
a lid disposed on the substrate, the lid comprising a plate portion covering the semiconductor package and a foot portion connecting the plate portion to the substrate, and the plate portion comprising a varying thickness.

13. The device of claim 12, wherein the plate portion of the lid comprises a first region and a second region surrounding the first region, the first region is directly over the semiconductor dies of the semiconductor package, and a first thickness of the plate portion in the first region is less than a second thickness of the plate portion in the second region.

14. The device of claim 12, wherein the plate portion of the lid comprises a bottom surface facing the semiconductor dies and a top surface opposite the bottom surface, and the top surface is flatter than the bottom surface.

15. The device of claim 12, further comprising:
a thermal interface material disposed on the plate portion of the lid, wherein the thermal interface material comprises a higher thickness uniformity than the lid; and
a heat-dissipating component disposed over the lid and thermally coupled to the lid through the thermal interface material.

16. A method, comprising:
coupling a semiconductor package to a substrate;
attaching a lid to the substrate and the semiconductor package, wherein the lid comprises a top surface and a bottom surface facing the semiconductor package; and
flattening the lid, wherein after flattening the lid, a flattened top surface of the lid is flatter than the bottom surface.

17. The method of claim 16, further comprising:
forming conductive terminals on the substrate;
mounting the substrate to a device component through the conductive terminals; and
performing a planarization process on the lid after mounting the substrate to the device component to flatten the lid.

18. The method of claim 16, further comprising:
forming conductive terminals on the substrate after flattening the lid by performing a planarization process on the lid; and
mounting the substrate to a device component through the conductive terminals.

19. The method of claim 18, wherein mounting the substrate to the device component comprises reflowing the conductive terminals, and during reflowing the conductive terminals, the flattened top surface of the lid is deformed.

20. The method of claim 16, further comprising:
providing the lid, wherein the top surface of the lid is concave, and after attaching the lid to the substrate and the semiconductor package, the lid is flattened.
